(19) United States
(12) Patent Application Publication
(10) Pub. No.: US 2014/0291744 A1
(43) Pub. Date: Oct. 2, 2014

(54) SPIN FET AND MAGNETORESISTIVE ELEMENT

(71) Applicant: Kabushiki Kaisha Toshiba, Tokyo (JP)

(72) Inventors: Yoshiaki SAITO, Kawasaki-shi (JP); Hideyuki Sugiyama, Kawasaki-shi (JP); Tomoaki Inokuchi, Kawasaki-shi (JP); Mizue Ishikawa, Yokohama-shi (JP)

(73) Assignee: Kabushiki Kaisha Toshiba, Tokyo (JP)

(21) Appl. No.: 14/300,876

(22) Filed: Jun. 10, 2014

Related U.S. Application Data
(62) Division of application No. 12/197,710, filed on Aug. 25, 2008.

(30) Foreign Application Priority Data
Aug. 28, 2007 (JP) 2007-221600

(51) Int. Cl. H01L 29/66

(52) U.S. Cl. CPC H01L 29/66984
USPC 257/295

(57) ABSTRACT

A spin FET of an aspect of the present invention includes source/drain regions, a channel region between the source/drain regions, and a gate electrode above the channel region. Each of the source/drain regions includes a stack structure which is comprised of a low work function material and a ferromagnet. The low work function material is a non-oxide which is comprised of one of Mg, K, Ca and Sc, or an alloy which includes the non-oxide of 50 at % or more.

### CROSS-REFERENCE TO RELATED APPLICATIONS

This application is based upon and claims the benefit of priority from prior Japanese Patent Application No. 2007-221600, filed Aug. 28, 2007, the entire contents of which are incorporated herein by reference.

### BACKGROUND OF THE INVENTION

1. Field of the Invention

The present invention relates to a spin FET and a magnetoresistive element.

2. Description of the Related Art

In recent years, a spin electronics device using spin freedom of electron has been researched and developed energetically. It has been proposed that the magnetoresistive element using a magnetic body film is used in a magnetic head, magnetic sensor and the like as well as a magnetic random access memory (MRAM) and spin transistor.

For example, technology of achieving a logic circuit having a reconfigurable function with the spin transistor has been proposed.

A current logic circuit is comprised of a combination of ordinary MOSFETs and in this case, the arrangement of the MOSFETs needs to be changed depending on logics such as AND, NOR, OR, and EX-OR. Contrary to this, according to the reconfigurable logic circuit, all logics can be achieved in one circuit only by changing data (for example, binary) to be recorded in a recording material of the spin transistor.

However, the reconfigurable logic circuit has a problem that its wiring may be complicated because a new circuit for recording data in a recording material is necessary.

Although the spin transistor includes various kinds such as diffusion type, Supriyo Datta type (spin orbit control type), spin valve type, single electron type and resonance type, any structure is not operated at a room temperature and has no amplifying function.

By the way, because the spin MOSFET using ferromagnet has the amplifying function at a room temperature, it is a potential candidate as the reconfigurable logic circuit (see, for example, Appl. Phys. Lett. 84(13) 2307 (2004)).

However, in the spin MOSFET using the ferromagnet, the semiconductor and ferromagnet make a direct contact with each other so that a Schottky barrier is generated therebetween. Consequently, ON resistance is raised, which is a problem. Further, if ferromagnetic transition temperature is lowered by mixing of the semiconductor and ferromagnet, the operation at a room temperature is disabled, which is another problem.

Accordingly, the spin MOSFET in which a tunnel barrier is disposed between the semiconductor and ferromagnet has been proposed (see, for example, JP-A 2006-32915 (KOKAI)).

Although the spin MOSFET having the tunnel barrier can solve the problem about the mixing of the semiconductor substrate and ferromagnet, the problem about lowering of the ON resistance is difficult to solve due to an existence of the tunnel barrier.

As regards the lowering of the ON resistance, technology of solving it by disposing rare earth element such as Gd, Er between the tunnel barrier and ferromagnet so as to reduce the effective barrier height has been proposed (see, for example, Byoung-Chul Min et al., Nature Materials vol. 5, 817 (2006)).

However, in this case, spin injection efficiency is lowered in return for lowering of the ON resistance, so that MR ratio drops, which is still another problem.

### BRIEF SUMMARY OF THE INVENTION

A spin FET of an aspect of the present invention is comprised of source/drain regions, a channel region between the source/drain regions, and a gate electrode above the channel region. Each of the source/drain regions includes a stack structure which is comprised of a low work function material and a ferromagnet. The low work function material is a non-oxide which is comprised of one of Mg, K, Ca and Sc, or an alloy which includes the non-oxide of 50 at % or more.

### BRIEF DESCRIPTION OF THE SEVERAL VIEWS OF THE DRAWING

FIG. 1 is a sectional view showing the basic structure of a spin FET;

FIG. 2 is a sectional view showing the basic structure of the spin FET;

FIG. 3 is a sectional view showing the basic structure of a junction FET;

FIG. 4 is a sectional view showing the basic structure of MESFET;

FIG. 5 is a sectional view showing the basic structure of a magnetoresistive element;

FIG. 6 is a sectional view showing the basic structure of the spin FET;

FIG. 7 is a sectional view showing the basic structure of the spin FET;

FIG. 8 is a sectional view showing the basic structure of the junction FET;

FIG. 9 is a sectional view showing the basic structure of the MESFET;

FIG. 10 is a sectional view showing the structure of a source/drain area;

FIG. 11 is an energy status diagram showing a band structure;

FIG. 12 is an energy status diagram showing the band structure;

FIG. 13 is a sectional view showing a spin FET as an application example;

FIG. 14 is a sectional view showing the spin FET as an application example;

FIG. 15 is a sectional view showing the spin FET as an application example;

FIG. 16 is a sectional view showing the spin FET as an application example;

FIG. 17 is a sectional view showing a magnetoresistive element as an application example;

FIG. 18 is a sectional view showing an MTJ structure of a first embodiment;

FIG. 19 is a diagram showing the device characteristic;

FIG. 20 is a sectional view showing the MTJ structure after anneal;

FIG. 21 is a diagram showing the device characteristic;

FIG. 22 is a diagram showing the device characteristic;

FIG. 23 is a sectional view showing the spin FET of a second embodiment;

FIG. 24 is a diagram showing the device characteristic;

FIG. 25 is a sectional view showing the spin FET after anneal;

FIG. 26 is a perspective view showing a magnetic disk unit of a fourth embodiment;

FIG. 27 is a perspective view showing a magnetic head assembly;

FIG. 28 is a sectional view showing the MTJ structure used for the magnetic head;

FIG. 29 is a diagram showing the device characteristic;

FIG. 30 is a sectional view showing the MTJ structure after anneal;

FIG. 31 is a sectional view showing the MTJ structure as a comparative example;

FIG. 32 is a diagram showing the device characteristic;

FIG. 33 is a diagram showing the device characteristic;

FIG. 34 is a sectional view showing the MTJ structure as a comparative example; and

FIG. 35 is a diagram showing the device characteristic.

### DETAILED DESCRIPTION OF THE INVENTION

A spin FET and a magnetoresistive element of an aspect of the present invention will be described below in detail with reference to the accompanying drawings.

### 1. OUTLINE

The feature of the spin FET of the present invention is that if the source/drain areas include a structure which is comprised of at least semiconductor substrate/tunnel barrier/ferromagnet, a low work function material is disposed between the tunnel barrier and ferromagnet.

Another feature of the spin FET of the invention is that if the source/drain areas of the spin FET include a structure which is comprised of at least semiconductor substrate, Schottky barrier, ferromagnet, a low work function material is disposed between the semiconductor substrate and ferromagnet.

The low work function material is defined below:

The low work function material is a material which is any one of non-oxide Mg, K, Ca, Sc or an alloy containing any one thereof at 50% or more in terms of the ratio of number of atoms. In this specification, the low work function material is not defined by a value of a work function. But, the word “low” is used in this specification, because the low work function material has a relative low work function.

Here, the at % means atomic %, based on atomic ratio.

Still another feature of the magnetoresistive element is that the magnetoresistive element has a structure comprised of at least substrate/ferromagnet/tunnel barrier/low work function material/ferromagnet, and the low work function material is any one of the non-oxide Mg, K, Ca, Sc or an alloy containing any one thereof at 50 at % or more.

Respect to the structure, the word “A/B/C” means a stack structure of “A”, “B” and “C” except the word “source/drain”. The word “source/drain” means “source” or “drain”.

Respect to the material, the word “A-B-C” means an alloy of “A”, “B” and “C”. The word (A, B, C) means a material which is one selected from a group of “A”, “B” and “C”.

In the spin MOSFET which conducts both charges and spin, when spin-polarized electrons are fed to a semiconductor, the spin injection efficiency into the semiconductor is lowered because resistance mismatch is large at an interface between the semiconductor and ferromagnet.

If a tunnel barrier is inserted between the semiconductor and the ferromagnet, mutual diffusion between the semiconductor and ferromagnet is suppressed and oxidation of ferromagnet at an interface between the both is suppressed. This is favorable for improvement of the spin MOSFET performance. Further, if a tunnel barrier exists, theoretically, the problem of conductance mismatch is solved.

However, in the structure of semiconductor/tunnel barrier/ferromagnet, Schottky barrier is formed in almost every case.

The height of the Schottky barrier is determined by the work function of the ferromagnet, electron affinity and Fermi level of the semiconductor. The tunnel probability of electrons via the Schottky barrier is increased exponentially with respect to an increase in voltage applied to the Shottky barrier. For this reason, dispersion of resistance under an operating voltage in the spin MOSFET is increased, thereby disabling integration of the spin MOSFET.

If the tunnel barrier and Schottky barrier are formed, both the barrier thickness and height need to be controlled. Thus, the dispersion of interface resistance is increased. If this dispersion is increased, integration of the spin MOSFET becomes further difficult to achieve.

Further, because the interface resistance (RA) is increased if the tunnel barrier and Schottky barrier are formed at the same time, there occurs such a problem that when the spin MOSFET is miniaturized, its resistance value becomes much larger than an expected value.

For example, because the work function of a metal-ferromagnet (alloy or compound containing Ni, Fe, Co) having a high polarization ratio is larger than electron affinity of silicon (Si), a high Shottky barrier is formed on an interface between the n-type semiconductor and ferromagnet. Thus, there occurs a problem that the interface resistance is increased too much.

If Gd (gadolinium) is inserted in between the tunnel barrier and ferromagnet as a low work function material, the height of the Shottky barrier is dropped, thereby lowering the interface resistance.

Although Gd is ferromagnet at a room temperature, if it adjoins a different ferromagnet from Gd, it is inclined to be magnetized easily anti-parallel with respect to a direction of magnetization of the other ferromagnet.

Thus, when injecting spin of other ferromagnet into semiconductor, electrons of the other ferromagnet cannot pass the Gd with the spin held. Although all devices need to withstand at least anneal at about 300° C., there occurs a problem that in the structure of Gd/tunnel barrier/semiconductor, the spin injection efficiency is lowered extremely after anneal so that the MR value drops.

The same thing holds true when other rare earth element than Gd is used.

For example, a case of Er has a problem that the MR value drops like the Gd.

Although the structure in which rare earth element such as Gd, Er is inserted has an advantage that the effective barrier height is lowered, a disadvantage that the MR ratio drops due to reduction of the spin injection efficiency occurs at the same time.

According to the present invention, as described above, by using any one of non-oxide Mg, K, Ca, Sc or an alloy containing any one thereof at 50 at % or more, lowering of the ON resistance due to lowering of the effective barrier height and improvement of the MR ratio due to a rise in the spin injection efficiency are achieved at the same time.

Further, according to the present invention, even if the tunnel barrier is not made thin, dielectric strength of the spin FET can be improved because the ON resistance can be lowered, thereby securing a high reliability.

Although when any one of Mg, K, Ca, Sc or an alloy containing any one thereof at 50 at % or more is inserted in between the semiconductor and tunnel barrier, the same effect can be obtained, following points need to be considered in this case.

In such a stack structure, after a low work function material such as Mg, K, Ca and Sc is formed, the tunnel barrier is formed. In this case, the possibility that the low work function material may be oxidized during formation of the tunnel barrier is high. If this amount of oxidation is increased, the effect of the lowering of the ON resistance cannot be obtained.

Therefore, if the low work function material is inserted in between the semiconductor and the tunnel barrier, a process of making the low work function material difficult to oxidize during the formation of the tunnel barrier is adopted and at the same time, the thickness t_{LW} of the low work function material needs to be increased (for example, t_{LW}≧1.2 nm (experimental value)).

In the meantime, the present invention is not restricted to the kinds of the spin FET but may be applied widely. Further, the spin FET of the present invention enables a reconfigurable logic circuit to be formed. Further, the present invention can be applied to the magnetic head (TMR head) and in this case, a TMR head having a large MR value can be achieved with a low resistance.

### 2. EMBODIMENTS

Embodiments of the spin FET of the present invention will be described.

In a description of following embodiments, drawings are schematic and the size of each component, ratio of the sizes between components, energy height, and energy ratio are different from actual ones. Even if the same components are represented in different drawings, some components are represented in a different dimension or ratio.

### (1) Basic Structure

First, the basic structure of the present invention will be described by taking the spin MOSFET, junction FET and metal semiconductor FET (MOSFET) as examples.

A. Tunnel Barrier Type Spin MOSFET (First Example)

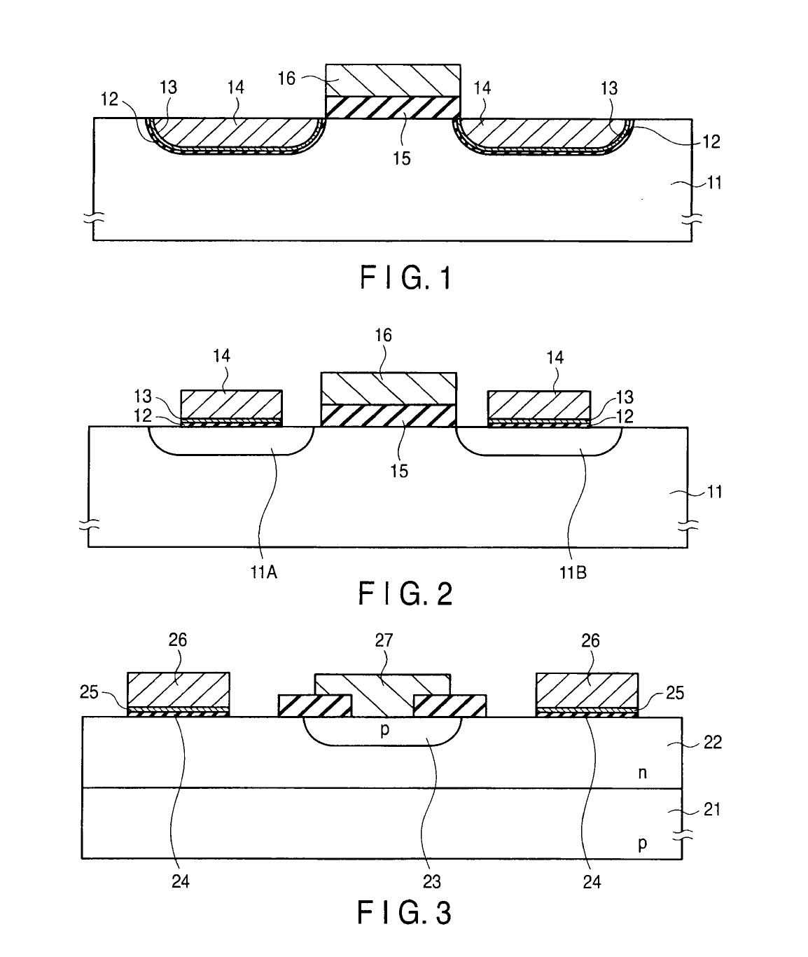

FIG. 1 shows the sectional structure of a tunnel barrier type spin MOSFET.

This spin MOSFET has a structure in which the source/drain diffusion layers of an ordinary MOSFET are replaced with ferromagnet.

A tunnel barrier 12, a low work function material 13 and ferromagnet 14 are disposed in a concave portion of a semiconductor substrate 11. The semiconductor substrate 11 may be either p-type or n-type. The low work function material 13 is comprised of any one of non-oxide Mg, K, Ca, Sc or an alloy containing any one thereof at 50 at % or more.

The low work function material 13 needs to have non-oxide portion and may contain oxidized portion.

A gate electrode 16 is disposed on a channel region between the ferromagnets 14 via a gate insulation film 15.

In this spin MOSFET, the source/drain areas are comprised of a stack structure of the semiconductor substrate 11, tunnel barrier 12, low work function material 13 and ferromagnet 14.

B. Tunnel Barrier Type Spin MOSFET (Second Example)

FIG. 2 shows the sectional structure of the tunnel barrier type spin MOSFET.

This spin MOSFET has a structure in which ferromagnet is disposed on the source/drain diffusion layers of the ordinary MOSFET.

Source/drain diffusion layers 11A, 11B are disposed on the surface region of the semiconductor substrate 11. If the semiconductor substrate 11 is of p-type, the source/drain diffusion layers 11A, 11B are of n-type and if the semiconductor substrate 11 is of n-type, the source/drain diffusion layers 11A, 11B are of p-type.

The tunnel barrier 12, low work function material 13 and ferromagnet 14 are disposed on the source/drain diffusion layers 11A, 11B. The low work function material 13 is comprised of any one of non-oxide Mg, K, Ca, Sc or an alloy containing any one thereof at 50 at % or more.

The low work function material 13 needs to have the non-oxide portion and may contain oxidized portion.

A gate electrode 16 is disposed on a channel region between the source/drain diffusion layers 11A, 11B via the gate insulation film 15.

In this spin MOSFET, the source/drain areas are comprised of a stack structure of the semiconductor substrate (source/drain diffusion layers) 11, tunnel barrier 12, low work function material 13 and ferromagnet 14.

C. Tunnel Barrier Type Junction FET

FIG. 3 shows the sectional structure of the tunnel barrier type junction FET.

A n-type region 22 is disposed on the surface region of a p-type semiconductor substrate 21. A p-type gate diffusion layer 23 is disposed in the n-type region 22. A tunnel barrier 24, low work function material 25 and ferromagnet 26 are disposed on the n-type region 22. The low work function material 25 is comprised of any one of non-oxide Mg, K, Ca, Sc or an alloy containing any one thereof at 50 at % or more.

The low work function material 25 needs to have the non-oxide portion and may contain oxidized portion.

A gate electrode 27 is disposed on the gate diffusion layer 23.

In the meantime, the p-type semiconductor substrate 21 and the p-type gate diffusion layer 23 may be replaced with a n-type and the n-type region 22 may be changed to a p-type.

In this junction FET, the source/drain areas are comprised of a stack structure of the semiconductor substrate 21, tunnel barrier 24, low work function material 25, and ferromagnet 26.

D. Tunnel Barrier Type MESFET

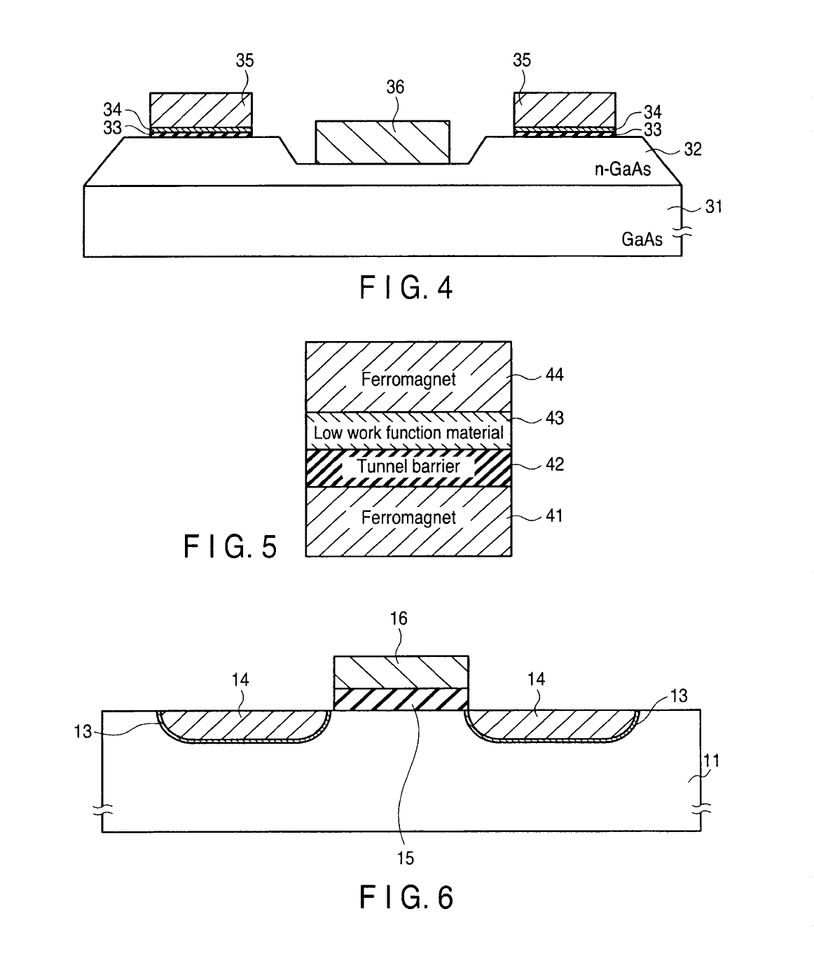

FIG. 4 shows the sectional structure of a tunnel barrier type MESFET.

A n-type GaAs layer 32 is disposed on the surface region of a semi-insulating GaAs substrate 31. Part of the n-type GaAs layer 32 is thin and a gate electrode 36 is disposed on that thin portion. A tunnel barrier 33, low work function material 34 and ferromagnet 35 are disposed on a thick portion of the n-type GaAs layer 32. The low work function material 34 is comprised of any one of the non-oxide Mg, K, Ca, Sc or an alloy containing any one thereof at 50 at % or more.

The low work function material 34 needs to have the non-oxide portion and may contain oxidized portion.

In the meantime, the n-type GaAs layer 32 may be replaced with p-type.

In this MESFET, the source/drain areas are comprised of a stack structure of the compound semiconductor layer 32, tunnel barrier 33, low work function material 34 and ferromagnet 35.

E. Tunnel Barrier Type Magnetoresistive Element

FIG. 5 shows the sectional structure of the tunnel barrier type magnetoresistive element.

A tunnel barrier 42 is disposed on a ferromagnet 41, and a low work function material 43 comprised of any one of the non-oxide Mg, K, Ca, Sc or an alloy containing any one thereof at 50 at % or more is disposed on the tunnel barrier 42. Further, a ferromagnet 44 is disposed on the low work function material 43.

The low work function material 43 needs to have the non-oxide portion and may contain an oxidized portion.

This kind of the tunnel barrier type magnetoresistive element is applied to the magnetic head (TMR head) or MRAM.

F. Schottky Barrier Type Spin MOSFET (First Example)

FIG. 6 shows the sectional structure of the Schottky barrier type spin MOSFET.

This spin MOSFET has a structure in which the source/drain diffusion layers of an ordinary MOSFET are replaced with ferromagnet.

The low work function material 13 and the ferromagnet 14 are disposed in a concave portion of the semiconductor substrate 11. The semiconductor substrate 11 may be either p-type or of n-type. The low work function material 13 is comprised of any one of the non-oxide Mg, K, Ca, Sc or an ally containing any one thereof at 50 at % or more.

The low work function material 13 needs to have the non-oxide portion and may contain an oxidized portion.

The gate electrode 16 is disposed on a channel region between the ferromagnets 14 via the gate insulation film 15.

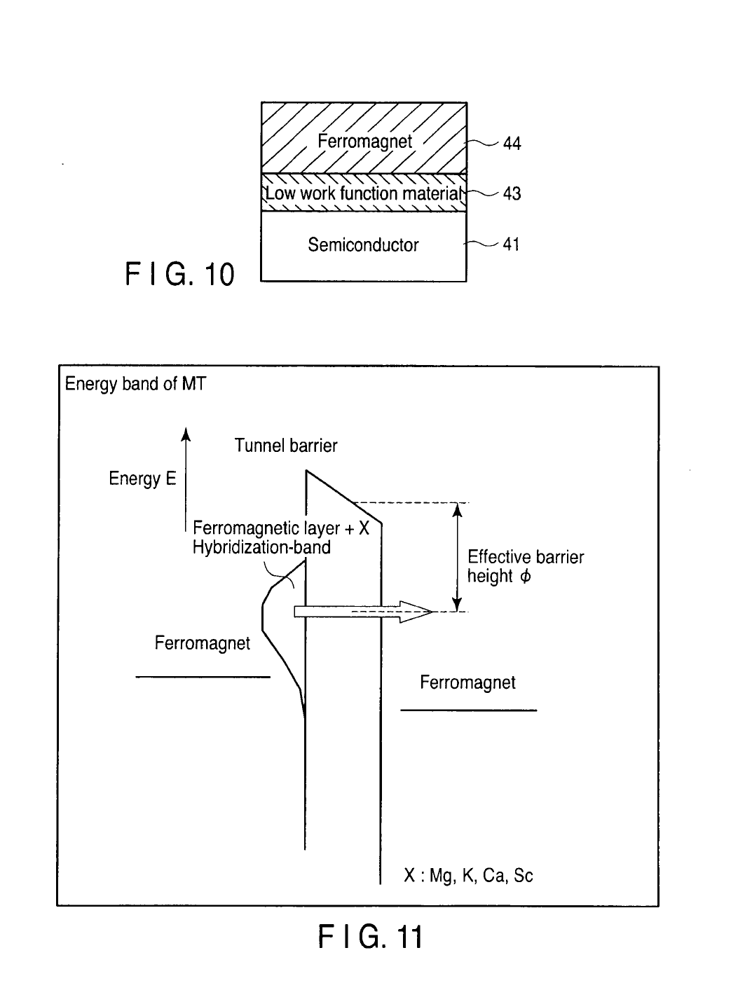

In this spin MOSFET, the source/drain areas are comprised of a stack structure of semiconductor, Schottky barrier, low work function material and ferromagnet, as shown in FIG. 10.

G. Schottky Barrier Type Spin MOSFET (Second Example)

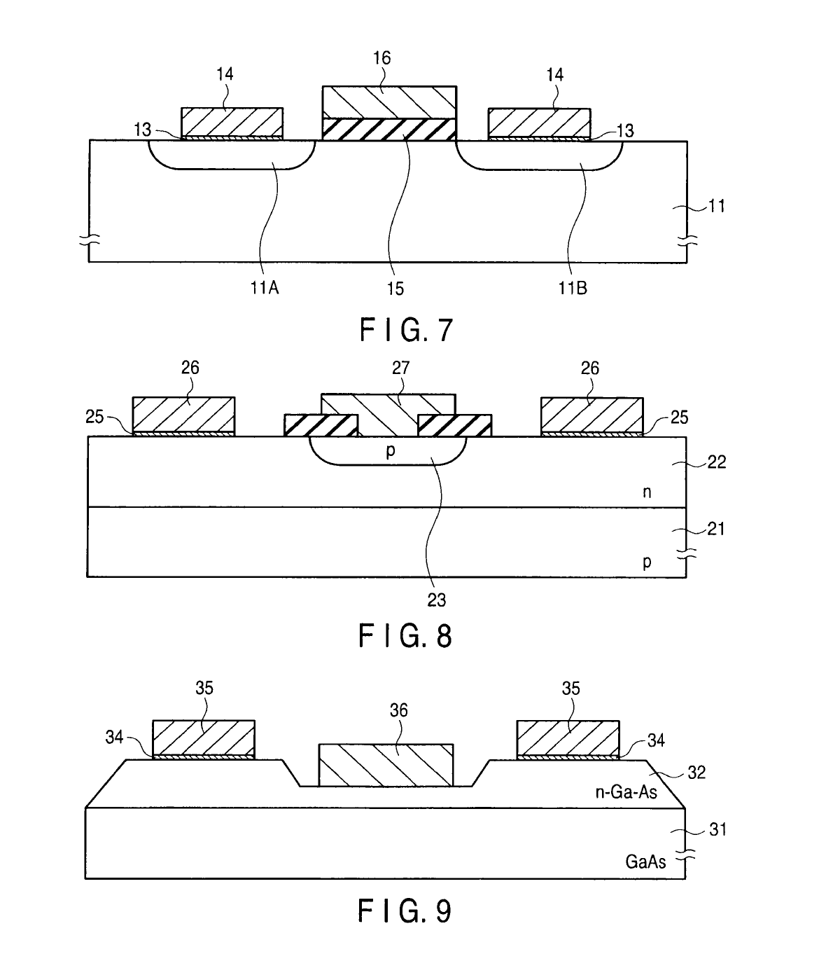

FIG. 7 shows the sectional structure of the Schottky barrier type spin MOSFET.

This spin MOSFET has a structure in which the ferromagnet is disposed on the source/drain diffusion layers of an ordinary MOSFET.

The source/drain diffusion layers 11A, 11B are disposed on the surface region of the semiconductor substrate 11. If the semiconductor substrate 11 is of p-type, the source/drain diffusion layers 11A, 11B are of n-type and if the semiconductor substrate 11 is of n-type, the source/drain diffusion layers 11A, 11B are of p-type.

The low work function material 13 and the ferromagnet 14 are disposed on the source/drain diffusion layers 11A, 11B. The low work function material 13 is comprised of any one of the non-oxide Mg, K, Ca, Sc or an alloy containing any one thereof at 50 at % or more.

The low work function material 13 needs to have the non-oxide portion and may contain an oxidized portion.

The gate electrode 16 is disposed on the channel region between the source/drain diffusion layers 11A, 11B via the gate insulation film 15.

In this spin MOSFET, the source/drain areas are comprised of a stack structure of the semiconductor (source/drain diffusion layers), Schottky barrier, low work function material, and ferromagnet.

H. Schottky Barrier Type Junction FET

FIG. 8 shows the sectional structure of the Schttoky barrier type junction FET.

The n-type region 22 is disposed on the surface region of the p-type semiconductor substrate 21. The p-type gate diffusion layer 23 is disposed in the n-type region 22. The low work function material 25 and the ferromagnet 26 are disposed on the n-type region 22. The low work function material 25 is comprised of any one of the non-oxide Mg, K, Ca, Sc or an alloy containing any one thereof at 50 at % or more.

The low work function material 25 needs to have the non-oxide portion and may contain an oxidized portion.

The gate electrode 27 is disposed on the gate diffusion layer 23.

In the meantime, the p-type semiconductor substrate 21 and the p-type gate diffusion layer 23 may be replaced with the n-type and the n-type region 22 may be changed to the p-type.

In this junction FET, the source/drain areas are comprised of a stack structure of the semiconductor, Shottky barrier, low work function material and ferromagnet as shown in FIG. 10.

I. Schottky Barrier Type MESFET

FIG. 9 shows the sectional structure of the Schottky barrier type MESFET.

The n-type GaAs layer 32 is disposed on the surface region of the semi-insulating GaAs substrate 31. Part of the n-type GaAs layer 32 is thin and the gate electrode 36 is disposed on that thin portion. Further, the low work function material 34 and ferromagnet 35 are disposed on a thick portion of the n-type GaAs layer 32. The low work function material 34 is comprised of any one of the non-oxide Mg, K, Ca, Sc or an alloy containing any one thereof at 50 at % or more.

The low work function material 34 needs to have the non-oxide portion and may contain an oxidized portion.

In the meantime, the n-type GaAs layer may be changed to the p-type.

In this MESFET, the source/drain areas are comprised of a stack structure of the semiconductor, Shottky barrier, low work function material and ferromagnet as shown in FIG. 10.

### (2) Energy Status Diagram

An effect obtained by using the low work function material of the present invention will be described by taking the tunnel barrier type as an example.

FIG. 11 is an energy status diagram of the magnetoresistive element.

The tunnel barrier is disposed between two ferromagnets. If the low work function material x of the present invention is disposed between the ferromagnet and the tunnel barrier, the position of hybridization band of the ferromagnetic layer containing the low work function material x becomes high thereby reducing the effective height of the tunnel barrier so as to obtain a low resistance magnetoresistive element.

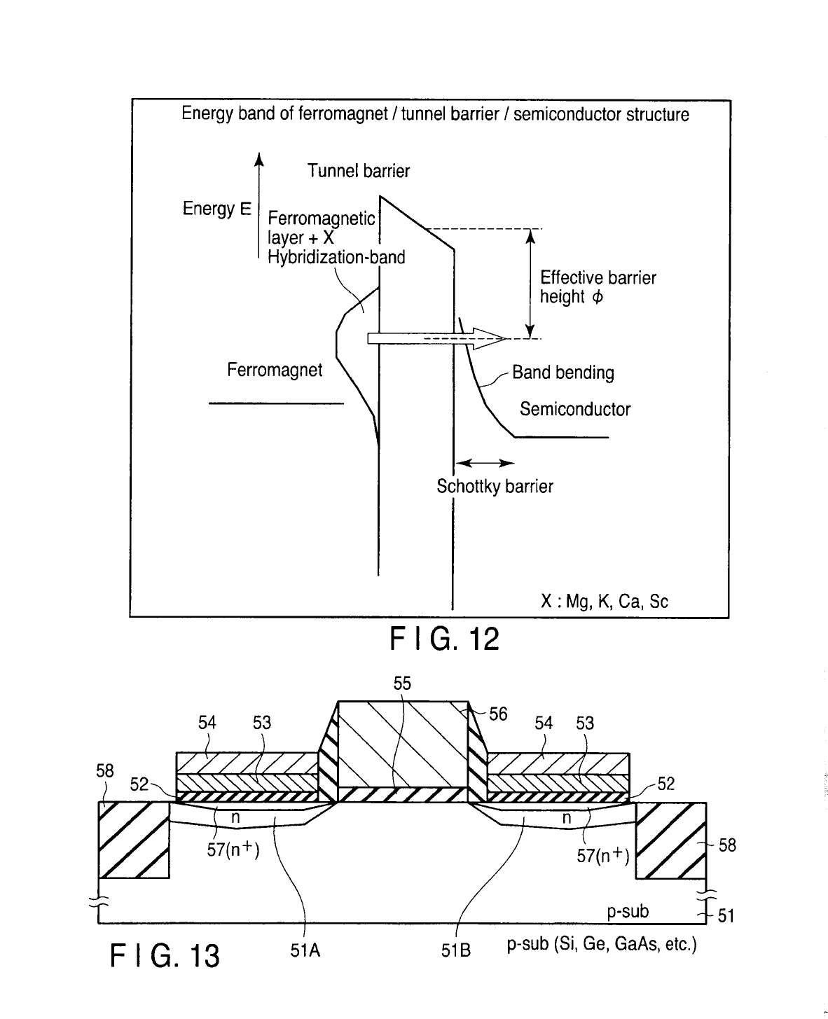

FIG. 12 is an energy status diagram of the stack structure of the spin FET.

The tunnel barrier is disposed between the semiconductor and the ferromagnet. In a semiconductor band, band bending occurs on an interface relative to the tunnel barrier. Also in this case, if the low work function material x of the present invention is disposed between the ferromagnet and the tunnel barrier, the hybridization band of the ferromagnetic layer containing the low work function material x becomes high thereby reducing the effective height of the tunnel barrier so as to obtain a low resistance spin FET.

Also in the Schottky barrier type, the effective height of the Schottky barrier is reduced by the ferromagnetic layer containing the low work function material. Consequently, a low resistance magnetoresistive element and spin FET can be achieved.

As the low work function material, yttrium (Y), terbium (Tb), dysprosium (Dy), holmium (Ho), gadolinium (Gd), erbium (Er), ytterbium (Yb) are available as well as Mg, K, Ca, Sc which the present invention is directed to.

However, these materials are not favorable for achieving both lowering of resistance and improvement of spin injection efficiency which are objects of the present invention. According to the present invention, as a result of verification about the individual low work function materials, it has been found that Mg, K, Ca, Sc, particularly Mg can achieve the lowering of resistance and improvement of spin injection efficiency at the same time.

### (3) Applications

The effect of the present invention becomes more significant by being combined with technology of lowering the height of the Schottky barrier generated in a junction between the ferromagnet and semiconductor and in the stack structure of the ferromagnet, tunnel barrier and semiconductor.

Hereinafter, the technology of lowering the height of the Schottky barrier will be described by taking the spin FET as an example.

FIG. 13 shows the sectional structure of the spin FET of the present invention.

The feature of this structure is that a problem about conductance mismatch originating from an increase of electric conductance between the semiconductor and ferromagnet has been solved by formation of a high density n⁺ diffusion layer on the surface region of a semiconductor substrate of Si, Ge, GaAs or the like.

Consequently, phenomenon that the spin polarization is saturated on the interface between the semiconductor and ferromagnet can be prevented, so that the spin can be injected into the semiconductor efficiently.

The specific structure will be described.

The p-type semiconductor substrate 51 is comprised of Si, Ge, GaAs or the like.

If GaAs is used for the semiconductor substrate 51, mobility of electron in the n-channel MOSFET is intensified, which is favorable. In this case, generally, Si is doped into the GaAs.

An element separation insulation layer 58 having shallow trench isolation (STI) structure is formed within the semiconductor substrate 51. n-type source/drain diffusion layers 51A, 51B are formed in an element region surrounded by the element separation insulation layer 58.

A tunnel barrier 52, low work function material 53 and ferromagnet 54 are stacked on the source/drain diffusion layers 51A, 51B. A gate electrode 56 is formed on a channel region between the source/drain diffusion layers 51A, 51B via a gate insulation film 55.

A high density n⁺ diffusion layer 57 is formed in a portion adjoining the tunnel barrier 52 of the semiconductor substrate 51.

In the meantime, the n⁺ diffusion layer 57 is formed by ion-injecting impurity such as phosphorus (P), arsenic (As) at acceleration energy of 20 KeV or less.

After ion-injection, rapid thermal anneal (RTA) is performed in nitrogen atmosphere. During this RTA, the anneal temperature is set to 1000 to 1100° C. if the semiconductor substrate 51 is Si, 400 to 500° C. if it is Ge, and 300 to 600° C. if it is GaAs.

The semiconductor substrate 51 may be of n-type. In this case, the n-type source/drain diffusion layers 51A, 51B and the n⁺ type diffusion layer 57 are of p-type.

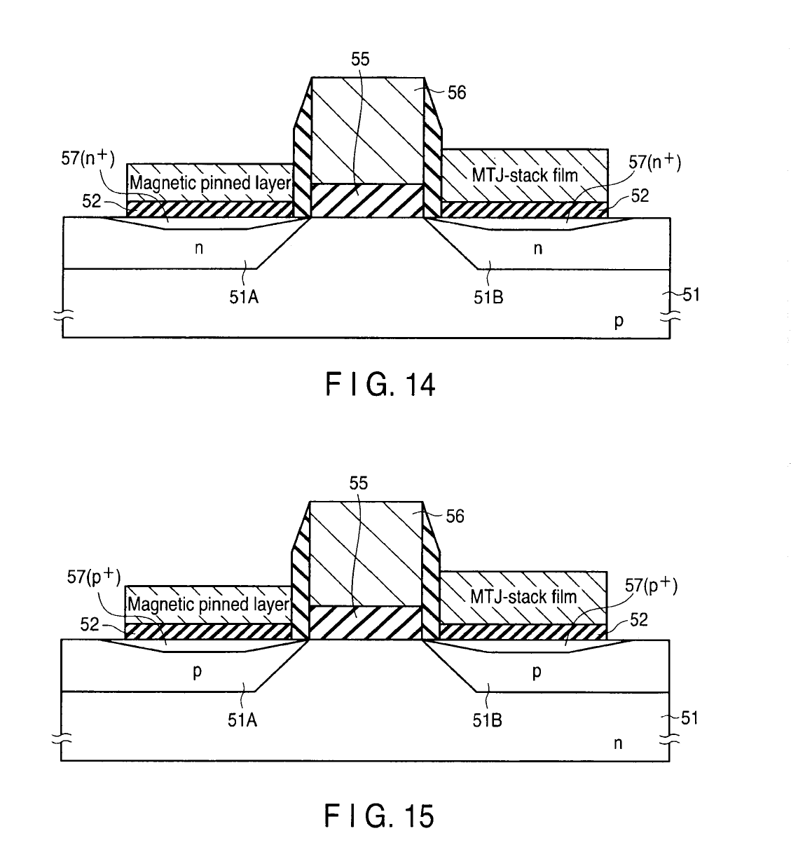

FIGS. 14 and 15 show the sectional structure of other application example of the spin FET of the present invention.

This structure is different from the structure of FIG. 13 in that one of two stack structures formed in the source/drain areas is of magnetic pinned layer. In the magnetic pinned layer, the magnetization direction of the ferromagnet is pinned. The magnetization direction of the ferromagnet can be pinned by, for example, antiferromagnet (IrMn, PtMn, NiMn or the like).

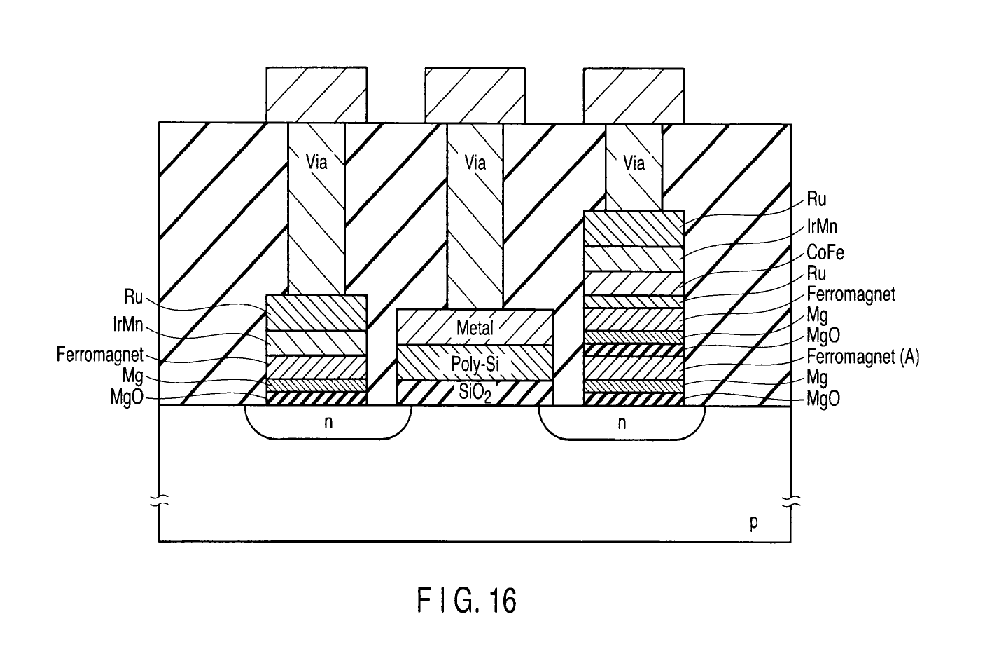

FIG. 16 shows a specific example of the spin FET of FIG. 14.

The stack structure (magnetic pinned layer) on the source/drain diffusion layers 51A is of MgO/Mg/ferromagnet/IrMn/Ru. The stack structure (MTJ laminated film) on the source/drain diffusion layers 51B is of MgO/Mg/ferromagnet/MgO/Mg/ferromanet/Ru/CoFe/IrMn/Ru.

When this structure is used, the spin torque acts on the ferromagnet (A) according to the direction of a current. Thus, the direction of the spin of the ferromagnet (A) can be changed easily and a signal output can be intensified by spin dependent conduction output via the semiconductor.

Another feature of this structure is that the ferromagnets are disposed on all MgO as the tunnel barrier via Mg. Consequently, lowering of the resistance can be achieved in all the tunnel barriers. Naturally, any one of K, Ca, Sc may be used instead of Mg.

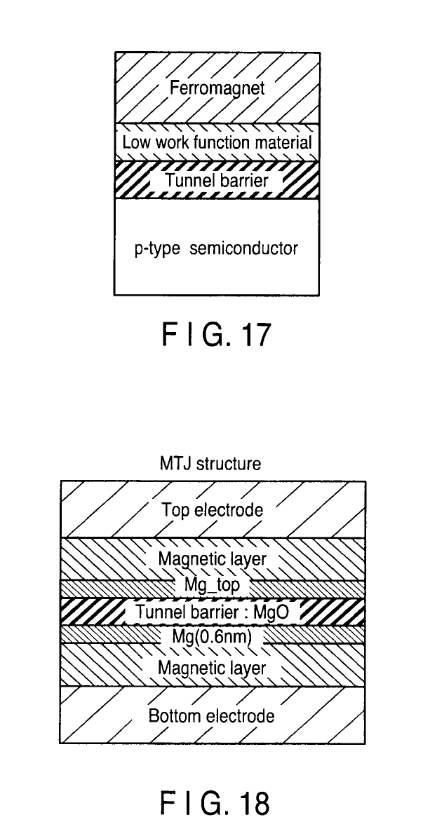

If a stack structure of p-type semiconductor, tunnel barrier, low work function material and ferromagnet is provided as shown in FIG. 17, it is preferable to mix at least any one of Pd, Os, Ir, Pt, Au and C in the ferromagnet.

### 3. EMBODIMENTS

The embodiments will be described below.

As regards the materials, A/B means lamination of A and B, (A,B,C) means selection of any one of A, B, C, and A-B means a compound or alloy containing A and B. Further, A (1 nm) means that the thickness of A is 1 nm.

### (1) First Embodiment

FIG. 18 shows a magnetoresistive element according to the first embodiment.

The MTJ structure includes bottom electrode (300 nm)/Ta (5 nm)/CoFeB (3 nm)/Mg (0.6 nm)/MgO (0.5 nm)/Mg (t_{Mg} nm)/CoFeB (4 nm)/Ru (0.9 nm)/CoFe (3 nm)/IrMn (10 nm)/Ta (5 nm)/top electrode (300 nm).

The magnetic layer adjacent to the bottom electrode corresponds to Ta (5 nm)/CoFeB (3 nm) and the magnetic layer adjacent to the top electrode corresponds to CoFeB (4 nm)/Ru (0.9 nm)/CoFe (3 nm)/IrMn (10 nm)/Ta (5 nm).

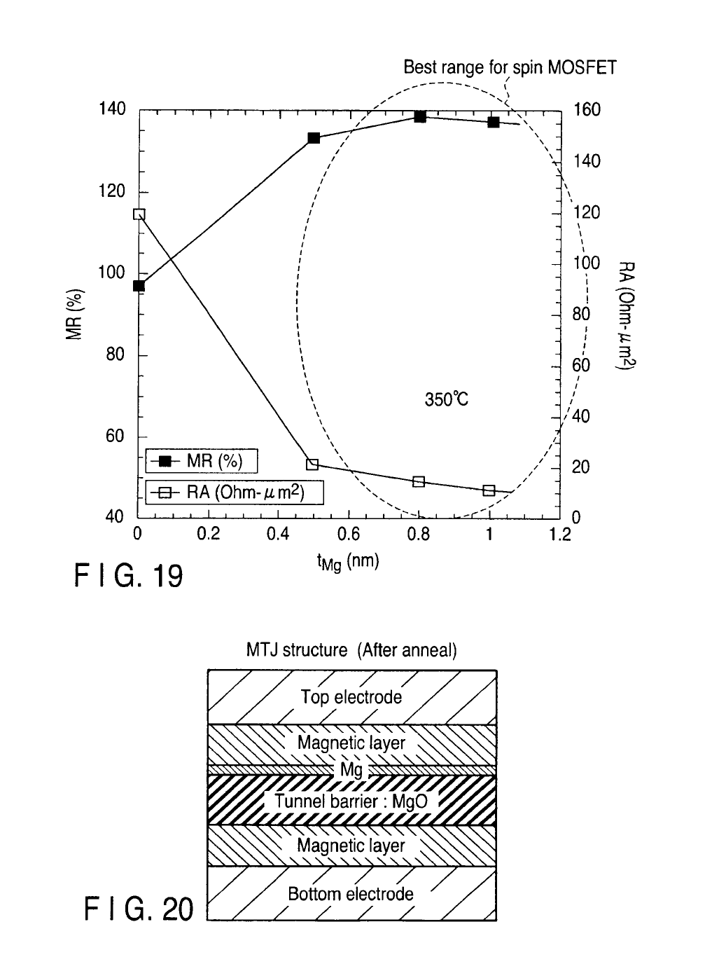

FIG. 19 shows the characteristic of the magnetoresistive element of FIG. 18.

The abscissa axis indicates a thickness t_{Mg} of the low work function material Mg top and the ordinate axis indicates an MR ratio (left scale) and element resistance RA (right scale).

The MR ratio and element resistance RA after anneal in a magnetic field (350° C., 1 hour) were obtained for each of the case where the thickness t_{Mg} of the low work function material Mg top was 0 nm, 0.5 nm, 0.8 nm, 1.0 nm. Consequently, a result shown in the same Figure was obtained.

As is evident from this result, the lowering of the element resistance (tunnel barrier) and improvement of the MR ratio can be achieved at the same time due to the existence of the low work function material Mg top of the present invention, as compared with a case where it does not exist.

After anneal in the magnetic field, as shown in FIG. 20, in the magnetoresistive element of FIG. 18, part of Mg between the tunnel barrier and magnetic layer is oxidized into MgO.

An important point exists in that non-oxide low work function material Mg is left on the tunnel barrier after anneal.

To confirm the existence of the non-oxide Mg, actually, XPS experiment was carried out after anneal. Consequently, non-oxide Mg was observed in all samples in which the thickness t_{Mg} of the low work function material Mg top was 0.5 nm or more.

The reason why all the Mg (0.6 nm) on the bottom electrode side of the tunnel barrier is changed to MgO is as follows. Although the tunnel barrier is formed after Mg is formed in a thickness of 0.6 nm on the magnetic layer, at this time, part of the Mg is oxidized into MgO.

Therefore, although in FIG. 18, the magnetoresistive element is described as Mg (0.6 nm), this is on design level and actually, before anneal, Mg just below the tunnel barrier is thinner than 0.6 nm or is all changed to MgO.

The same experiment was carried out for K, Ca, Sc instead of the low work function material Mg top, and consequently, substantially the same result was obtained.

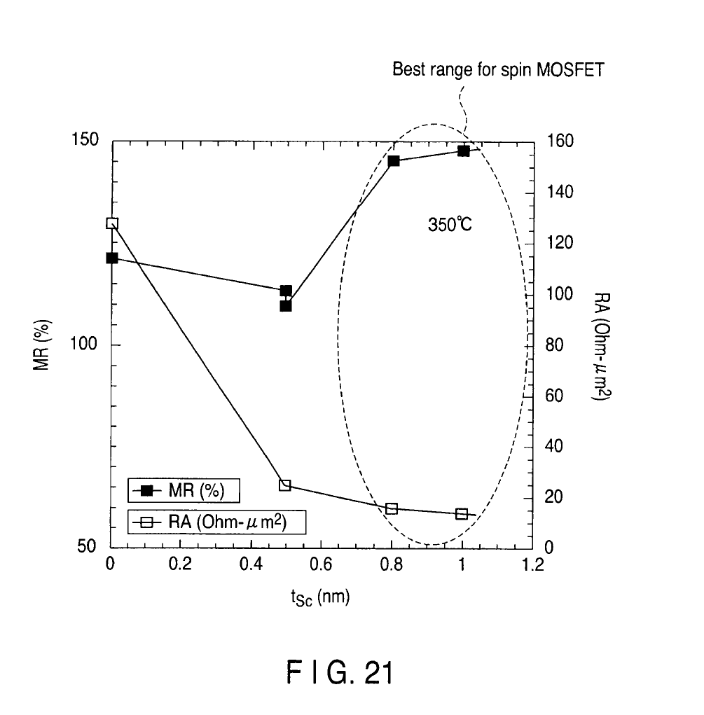

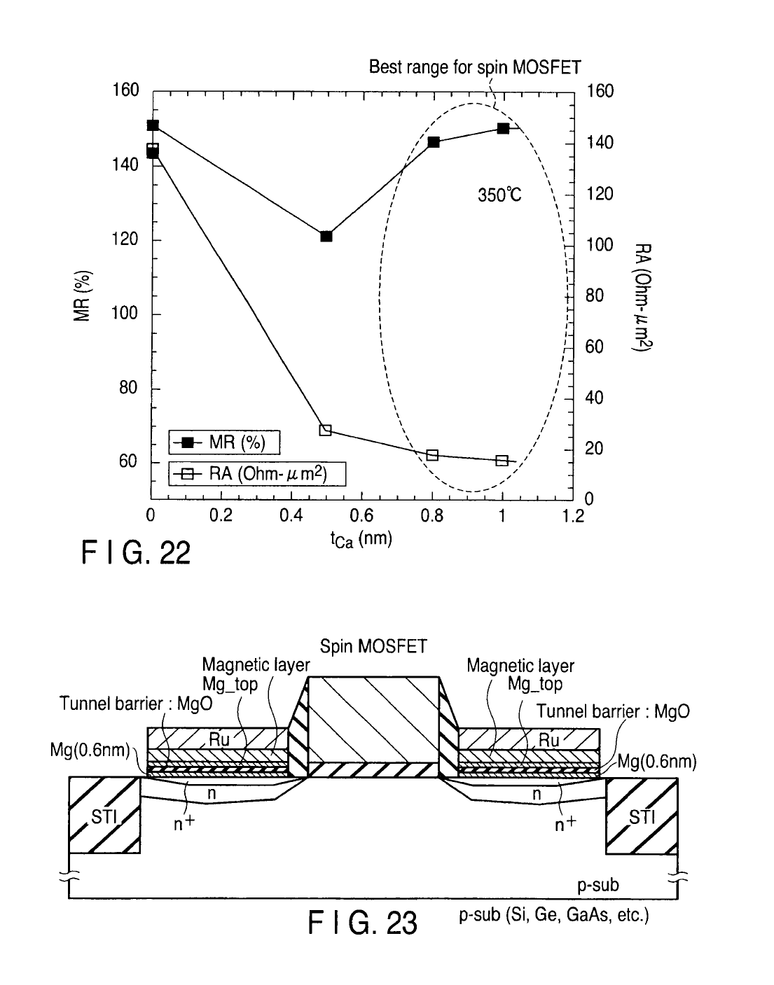

FIG. 21 shows a result of using Sc as the low work function material and FIG. 22 shows a result of using Ca.

Because the present invention can achieve both the lowering of resistance and improvement of the MR ratio, it is very preferable that the magnetoresistive element is applied to such devices as the spin FET, magnetic head, and MRAM.

### (2) Second Embodiment

FIG. 23 shows a spin MOSFET of the second embodiment.

First, a silicon substrate in which polycrystal silicon (gate), silicon dioxide (gate oxide film), p-type doped silicon (p-channel) are formed is prepared, and phosphorus (P) is doped into a region in which ferromagnet is to be formed at 10¹⁷ atoms/cm² so as to form n-type silicon (n-Si).

Further, using a high vacuum chamber, Mg (0.6 nm)/MgO (1 nm)/Mg (0.8 nm)/ferromagnet Co₂FeSi_{0.5}Al_{0.5} (5 nm) are formed on the n-type silicon continuously by sputtering. Ru (ruthenium) is formed as a cap layer on the ferromagnet.

The ferromagnet here may be Heusler alloy: Co₂FeSi_{0.5}Al_{0.5} (5 nm)/Ru (1 nm)/CoFe (5 nm)/IrMn (10 nm) instead of Co₂FeSi_{0.5}Al_{0.5} (5 nm) single layer. Although this embodiment adopts the MTJ structure, it is permissible to adopt the current perpendicular in plane-giant magnetoresistance (CPP-GMR) structure instead of this.

A resist pattern is formed by photolithography. The stack structure on the source/drain diffusion layers is patterned by ion milling.

After the resist pattern is separated, SiO₂ is formed as an interlayer insulation film according to the CVD method and a resist pattern is formed again by photolithography. Further, the interlayer insulation film is etched with this pattern used as a mask by reactive ion etching (RIE) so as to form via holes.

After the resist pattern is separated, wiring layer is formed of lamination of Ti/Al/Ti by sputtering and a resist pattern is formed again by photolithography. Further, by using this as a mask, the wiring layer is etched by RIE so as to form a wiring pattern.

In the above-described spin MOSFET, spin-polarized electron is conducted through a path of Co₂FeSi_{0.5}Al_{0.5}/Mg/MgO/n-Si/p-channel/n-Si/MgO/Mg/Co₂FeSi_{0.5}Al_{0.5}. Interface resistance (RA) of this path is 110 Ω·μm² and the magnetic resistance change ratio (MR ratio) is 24.6%.

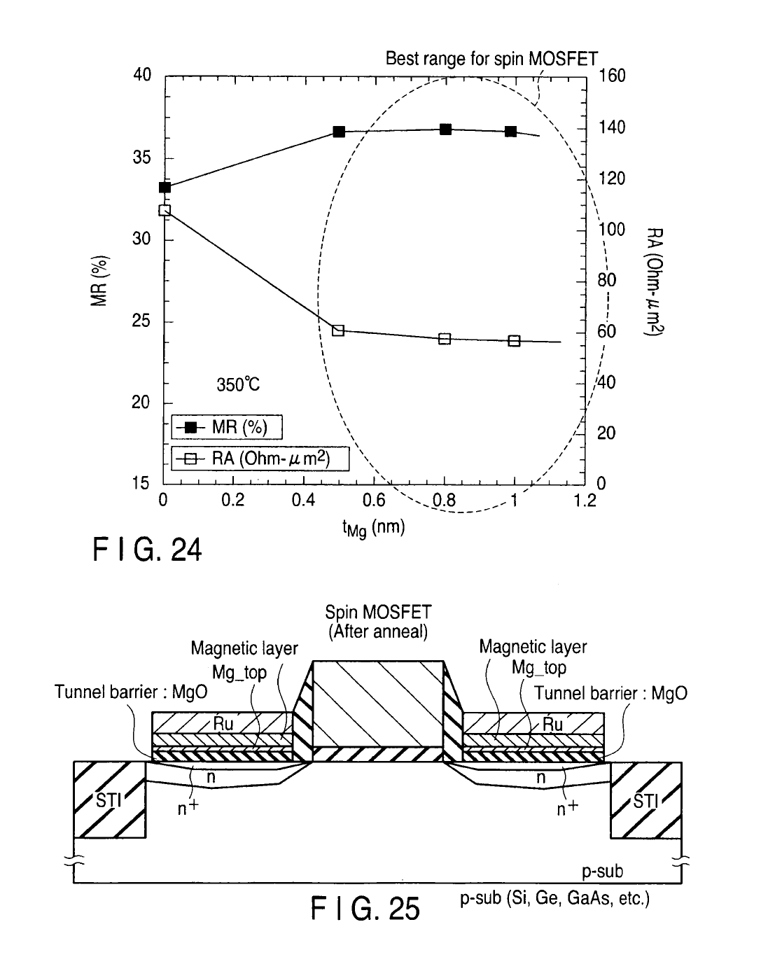

FIG. 24 shows the characteristic of the spin MOSFET of FIG. 23.

The abscissa axis indicates a thickness t_{Mg} of the low work function material Mg top and the ordinate axis indicates an MR ratio (left scale) and element resistance RA (right scale).

The MR ratio and element resistance RA after anneal in a magnetic field (350° C., 1 hour) were obtained for each of the case where the thickness t_{Mg} of the low work function material Mg top was 0 nm, 0.5 nm, 0.8 nm, 1.0 nm. Consequently, a result shown in the same Figure was obtained.

As is evident from this result, the lowering of the element resistance (tunnel barrier) and improvement of the MR ratio can be achieved at the same time due to the existence of the low work function material Mg top of the present invention, as compared with a case where it does not exist.

After anneal in the magnetic field, as shown in FIG. 25, in the spin MOSFET of FIG. 23, part of Mg between the tunnel barrier and magnetic layer is oxidized into MgO.

An important point is that, as described in the first embodiment, even after anneal, any non-oxide low work function material Mg is left on the tunnel barrier.

To confirm the existence of the non-oxide Mg, actually, XPS experiment was carried out after anneal. Consequently, non-oxide Mg was observed in all samples in which the thickness t_{Mg} of the low work function material Mg top was 0.5 nm or more.

The same experiment was carried out for K, Ca, Sc instead of the low work function material Mg top, and consequently, substantially the same result was obtained.

As described above, according to the present invention, the lowering of resistance and improvement of the MR ratio can be achieved at the same time in the spin MOSFET.

As a semiconductor substrate for forming the spin MOSFET, silicon (Si), gallium arsenic (GaAs), germanium (Ge), silicon germanium (SiGe), zinc selenium (ZnSe) are available.

As the dopant for n-type source/drain diffusion layers and n⁺ type diffusion layer, boron (B), aluminum (Al), gallium (Ga), silicon (Si) and germanium (Ge) are available.

As the tunnel barrier, such insulators as magnesium oxide (MgO), aluminum oxide (Al₂O₃), silicon oxide (SiO₂), aluminum nitride (AlN), bismuth oxide (Bi₂O₃), magnesium fluoride (MgF₂), calcium fluoride (CaF₂), strontium titanate (SrTiO₃), lanthanum aluminate (LaAlO₃), aluminum nitride oxide (Al—N—O), and hafnium oxide (HfO) are available.

The thickness of the tunnel barrier needs to be 0.42 nm or more in order to cover the surface completely and needs to be 5 nm or less so as to obtain a tunnel current. Further, if the spin MOSFET is highly integrated, the tunnel barrier is 2.1 nm or less, more preferably 1.1 nm or less so as to obtain a low interface resistance RA.

The ferromagnet is comprised of a thin film of at least one kind selected from the group comprising of Ni—Fe, Co—Fe, Co—Fe—Ni, CoFeB, (Co, Fe, Ni)—(Si, B), (Co, Fe, Ni)—(Si, B)—(P, Al, Mo, Nb, Mn) base, amorphous material such as Co—(Zr, Hf, Nb, Ta, Ti) film, and Heusler material such as Co₂(MnₓFe₁₋ₓ)Si, Co₂Fe(AlₓSi₁₋ₓ), Co₂Mn(AlₓSi₁₋ₓ), or Co₂MnGe, where or multilayer film thereof.

For these ferromagnets, various physical properties such as magnetic characteristic, crystallinity, mechanical characteristic, chemical characteristic can be adjusted by adding non-magnetic elements such as silver (Ag), copper (Cu), gold (Au), aluminum (Al), magnesium (Mg), silicon (Si), bismuth (Bi), tantalum (Ta), boron (B), carbon (C), oxygen (O), nitrogen (N), palladium (Pd), platinum (Pt), zirconium (Zr), iridium (Ir), tungsten (W), molybdenum (Mo), and niobium (Nb).

The low work function material is required to have a lower work function. Further, it is required not to lower the spin injection efficiency. As a result of search for materials which satisfy those requirements, the inventors have found out that magnesium (Mg), scandium (Sc), calcium (Ca) and potassium (K) are optimum.

The low work function material may be an alloy having a low work function comprised of mainly the aforementioned elements, magnesium (Mg), scandium (Sc), calcium (Ca) and potassium (K). If any alloy having the low work function is used, in terms of the components of the alloy in ratio of numbers of atoms, the total of magnesium (Mg), scandium (Sc), calcium (Ca) and potassium (K) is preferred to be 50% or more.

The thickness of the low work function material is 0.2 nm or more so as to obtain a low work function, more preferably 0.25 nm or more. Further, the thickness of the low work function material is preferred to be 5 nm or less in order to prevent the spin of a spin-polarized electron from being diffused and preferred to be 2 nm or less so as to obtain high spin injection efficiency.

### (3) Third Embodiment

The third embodiment relates to the spin MOSFET, in which the tunnel barrier, non-magnetic low work function material, ferromagnet and Pt are formed on the p-type semiconductor.

Hereinafter, the formation method thereof will be described.

First, a silicon substrate in which polycrystal silicon (gate), silicon dioxide (gate oxide film), n-type doped silicon (n-channel) are formed is prepared, and boron (B) is doped into a region in which ferromagnet is to be formed at 10¹⁷ atoms/cm² so as to form p-type silicon (p-Si).

Further, using a high vacuum chamber, Mg (0.7 nm)/MgO (0.45 nm)/Mg (1 nm)/ferromagnet (CoFe)₅₀Pt₅₀ (1 nm)/CoFeB (3 nm) are formed continuously on the p-type silicon by sputtering. Ru (ruthenium) is formed as a cap layer on the ferromagnet.

For the MTJ structure, Mg (0.7 nm)/MgO (0.45 nm)/Mg (1 nm)/CoFeB (3 nm)/Ru (0.9 nm)/CoFe (4 nm)/IrMn (10 nm)/Ru are formed on the ferromagnet CoFeB (3 nm).

The entire structure of the spin MOSFET is produced according to the same method as the second embodiment.

As for etching by ion milling, CoFe and (CoFe)₅₀Pt₅₀ is etched continuously.

About the spin MOSFET formed in this way, it was confirmed that the spin injection was carried out via the semiconductor when gate voltage was applied.

As a result of observing the spin dependent conduction via a semiconductor at the time of ON, the interface resistance RA was 232 Ω·μm² and the magnetic resistance change ratio (MR ratio) was 89%.

In the third embodiment, a high MR ratio can be achieved with a low resistance RA.

In the meantime, various kinds of the semiconductor materials, ferromagnet materials and tunnel barrier materials can be used like the second embodiment.

In the third embodiment, by including at least one of palladium (Pd), osmium (Os), iridium (Ir), platinum (Pt), gold (Au) and carbon (C) in the ferromagnet at 50 at % or more, an alloy layer of these elements with the low work function material can be formed.

In this case, when carbon (C) was included in the ferromagnetic material, the MR ratio could be raised most (99%).

### (4) Fourth Embodiment

Next, an embodiment in which the magnetoresistive element of the present invention is applied to the TMR head used as a hard disc drive (HDD) reading head will be described below.

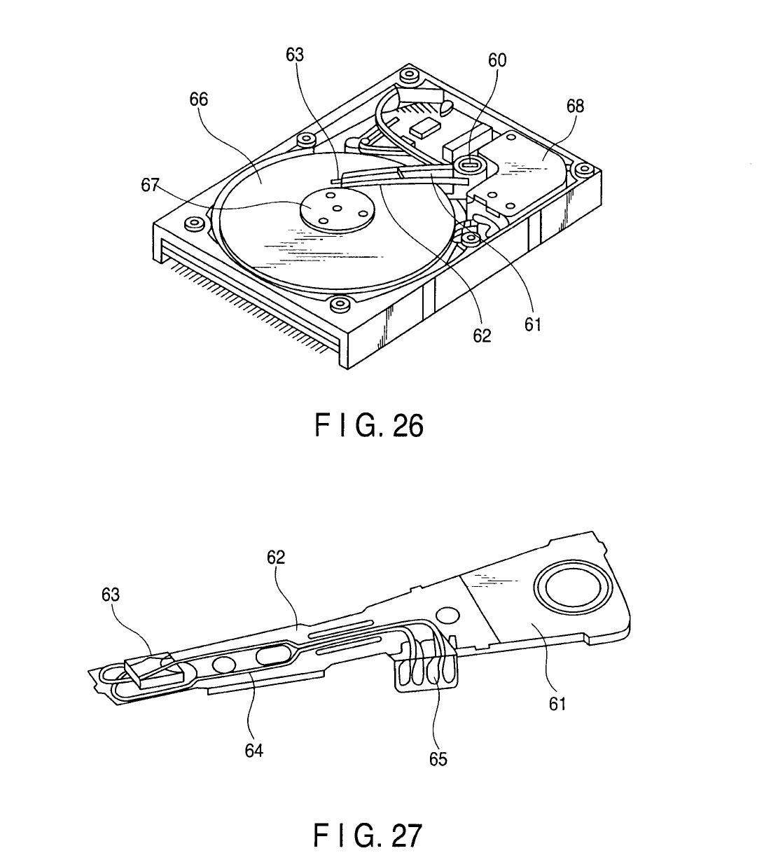

FIG. 26 shows the internal structure of a magnetic disk unit. FIG. 27 shows a magnetic head assembly loaded with a TMR head.

An actuator arm 61 has a hole for being fixed to a fixing shaft 60 within the magnetic disk unit and a suspension 62 is connected to an end of the actuator arm 61.

A head slider 63 loaded with the TMR head is attached to the front end of the suspension 62. A lead line 64 is placed on the suspension 62 for writing/reading of data.

An end of this lead line 64 is connected electrically to an electrode of the TMR head incorporated in the head slider 63.

The other end of the lead line 64 is connected to an electrode pad 65.

A magnetic disk 66 is mounted on a spindle 67 and driven by a motor according to a control signal from a drive control portion.

The head slider 63 is floated by a predetermined amount by rotation of the magnetic disk 66. With this state, data is recorded or reproduced using the TMR head.

The actuator arm 61 has a bobbin portion which holds a drive coil. A voice coil motor 68, which is a kind of the linear motor, is connected to the actuator arm 61.

The voice coil motor 68 has a magnetic circuit which includes a drive coil wound up by the bobbin portion of the actuator arm 61, and a permanent magnet and an opposing yoke which are disposed in opposing relation so as to sandwich this coil.

The actuator arm 61 is held by ball bearings provided at two positions which are upper and lower of the fixing shaft 60. And the actuator arm 61 is driven by the voice coil motor 68.

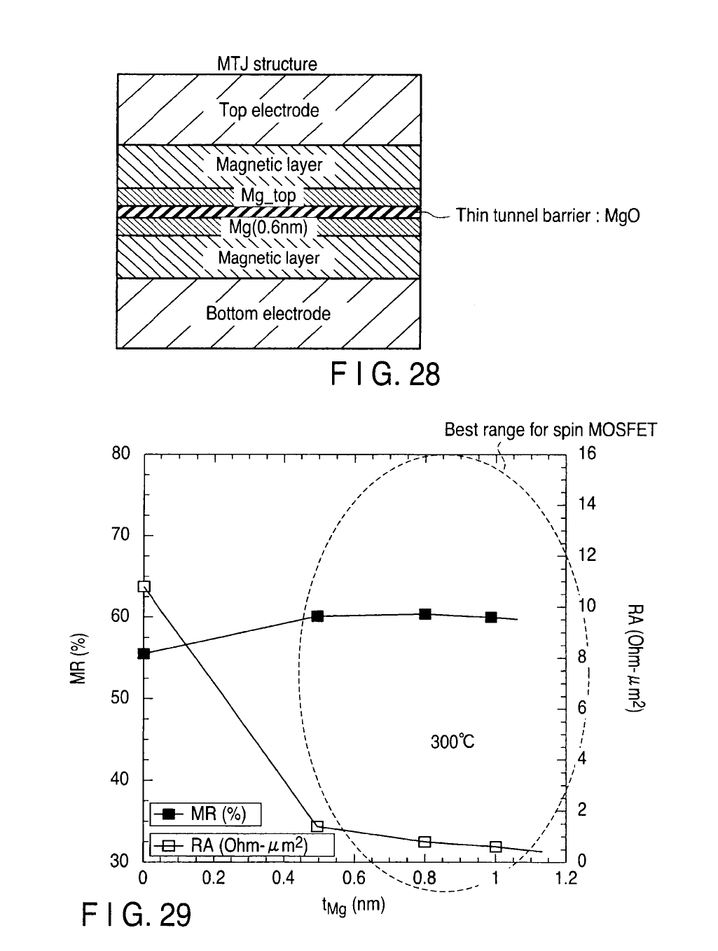

FIG. 28 shows a structure example of the magnetoresistive element for use in the aforementioned TMR head.

The MTJ structure includes bottom electrode (300 nm)/Ta (3 nm)/CoFeB (3 nm)/Mg (0.6 nm)/MgO (0.35 nm)/Mg (t_{Mg} nm)/CoFeB (4 nm)/Ru (0.9 nm)/CoFe (3 nm)/IrMn (9 nm)/Ta (5 nm)/top electrode (300 nm).

The magnetic layer adjacent to the bottom electrode corresponds to Ta (3 nm)/CoFeB (3 nm) and the magnetic layer adjacent to the top electrode corresponds to CoFeB (4 nm)/Ru (0.9 nm)/CoFe (3 nm)/IrMn (9 nm)/Ta (5 nm). The antiferromagnet which is pinned a magnetization direction of the ferromaget is corresponding to IrMn.

The characteristic of this magnetoresistive element is shown in FIG. 29.

The abscissa axis indicates a thickness t_{Mg} of the low work function material Mg top and the ordinate axis indicates an MR ratio (left scale) and element resistance RA (right scale).

The MR ratio and element resistance RA after anneal in a magnetic field (350° C., 1 hour) were obtained for each of the case where the thickness t_{Mg} of the low work function material Mg top was 0 nm, 0.5 nm, 0.8 nm, 1.0 nm. Consequently, a result shown in the same Figure was obtained.

As is evident from this result, the lowering of the element resistance (tunnel barrier) and improvement of the MR ratio can be achieved at the same time due to the existence of the low work function material Mg top of the present invention, as compared with a case where it does not exist.

This result is very preferable as the characteristic of the magnetic head.

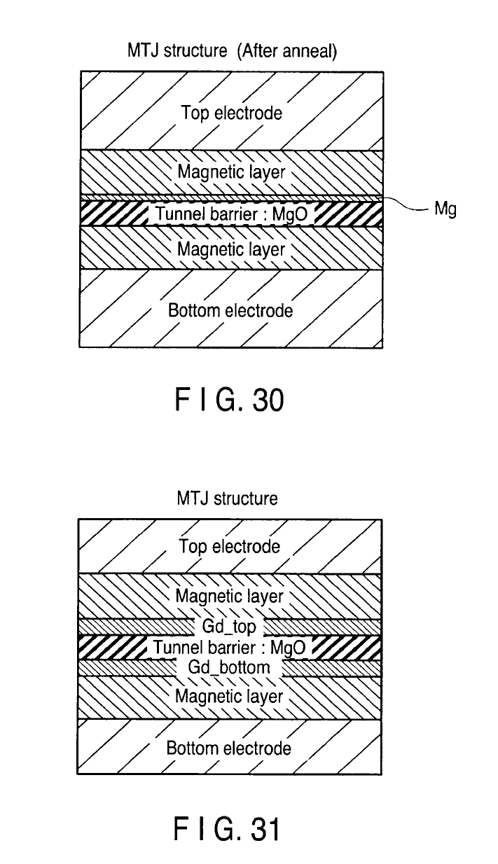

Like the first embodiment, to confirm the existence of the non-oxide Mg, actually, XPS experiment was carried out after anneal. Consequently, as shown in FIG. 30, non-oxide Mg was observed in all samples in which the thickness t_{Mg} of the low work function material Mg top was 0.5 nm or more.

It is preferable that the thickness of the low work function material is 0.5 nm or more to 5 nm or less.

The same experiment was carried out for K, Ca, Sc instead of the low work function material Mg top, and consequently, substantially the same result was obtained.

As a result of measurement of barrier dielectric strength, no destruction was found up to 1.5V, thereby confirming that the reliability was not deteriorated.

Although, as the tunnel barrier material, magnesium oxide (MgO) was used here, when aluminum oxide (Al₂O₃), silicon oxide (SiO₂), aluminum nitride (AlN), bismuth oxide (Bi₂O₃), magnesium fluoride (MgF₂), calcium fluoride (CaF₂), strontium titanate (SrTiO₃), lanthanum aluminate (LaAlO₃), aluminum nitride oxide (Al—N—O), or hafnium oxide (HfO) was used, the effects about the lowering of resistance and improvement of the MR ratio could be confirmed.

Because according to the present invention, the lowering of resistance and improvement of the MR ratio can be achieved at the same time, the characteristic of the magnetic head can be improved.

### (5) Comparative Examples

FIG. 31 shows a magnetoresistive element according to the comparative example.

The MTJ structure includes bottom electrode (300 nm)/Ta (5 nm)/CoFeB (3 nm)/Gd (t Gd bottom nm)/MgO (0.5 nm)/Gd (t_{Gd top} nm)/CoFeB (4 nm)/Ru (0.9 nm)/CoFe (3 nm)/IrMn (10 nm)/Ta (5 nm)/top electrode (300 nm).

The magnetic layer adjacent to the bottom electrode corresponds to Ta (5 nm)/CoFeB (3 nm) and the magnetic layer adjacent to the top electrode corresponds to CoFeB (4 nm)/Ru (0.9 nm)/CoFe (3 nm)/IrMn (10 nm)/Ta (5 nm).

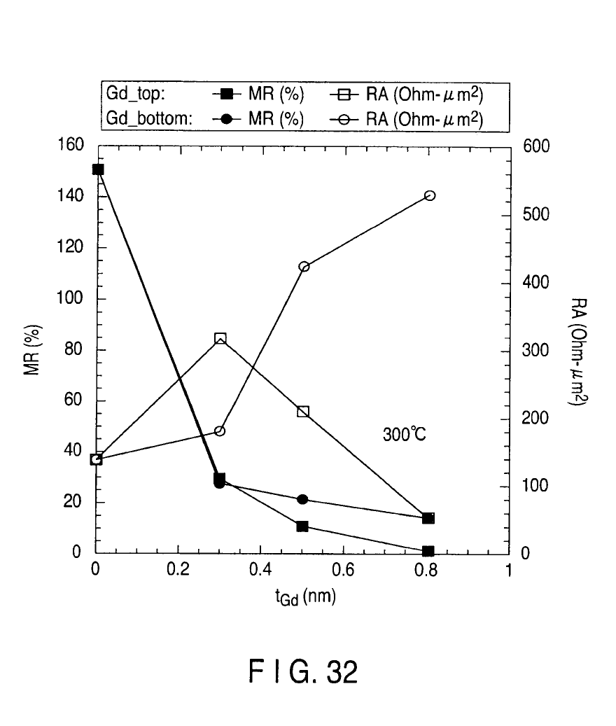

FIG. 32 shows the characteristic of the magnetoresistive element of FIG. 31.

The abscissa axis indicates a thickness t_{Gd bottom}, t_{Gd top} of the low work function material Gd and the ordinate axis indicates an MR ratio (left scale) and element resistance RA (right scale).

The MR ratio and element resistance RA after anneal in a magnetic field (350° C., 1 hour) were obtained for each of the case where the thickness t_{Gd bottom} of the low work function material Gd was 0 nm, 0.3 nm, 0.5 nm, 0.8 nm. Consequently, a result shown in the same Figure was obtained.

As is evident from this result, when Gd is used as the low work function material, if Gd exists just above the tunnel barrier (MR ratio: black circle, RA: white circle), the element resistance value is not changed much and the MR ratio is decreased. If Gd exists just below the tunnel barrier (MR ratio: black square, RA: white square), the element resistance value is increased and the MR ratio is decreased.

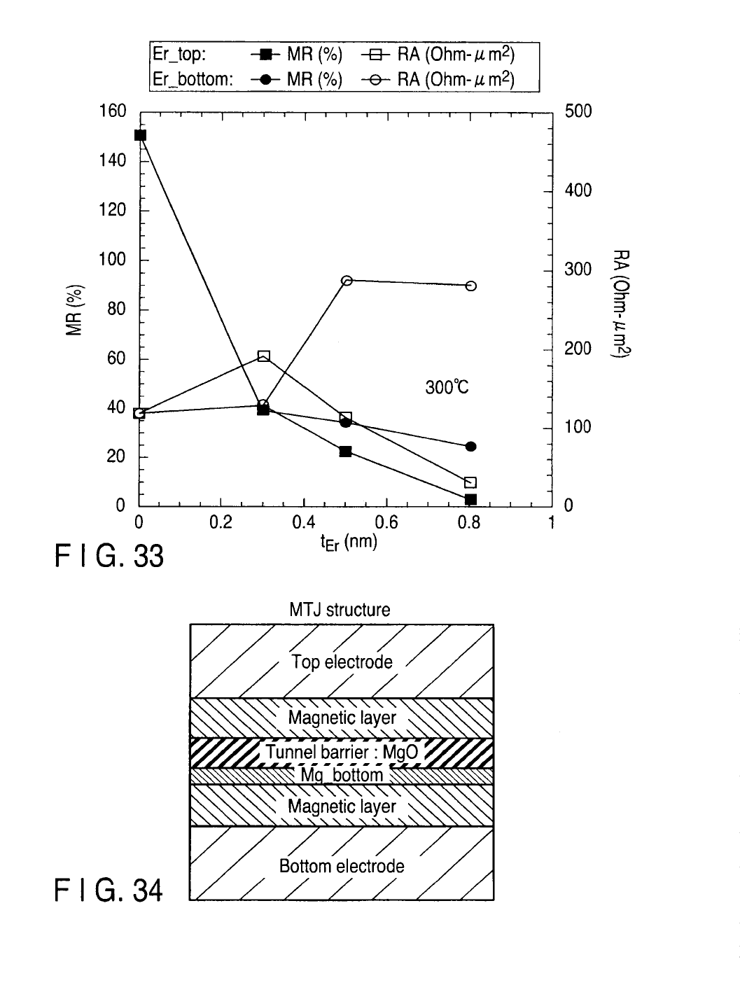

FIG. 33 shows a comparative example when Er is used as the low work function material.

Assume that the MTJ structure is the same as the case of Gd (FIG. 31).

The abscissa axis indicates a thickness t_{Er bottom}, t_{Er top} of the low work function material Er and the ordinate axis indicates an MR ratio (left scale) and element resistance RA (right scale).

The MR ratio and element resistance RA after anneal in a magnetic field (350° C., 1 hour) were obtained for each of the case where the thickness t_{Er bottom} of the low work function material Er was 0 nm, 0.3 nm, 0.5 nm, 0.8 nm. Consequently, a result shown in the same Figure was obtained.

As is evident from this result, when Er is used as the low work function material, if Er exists just above the tunnel barrier (MR ratio: black circle, RA: white circle), the element resistance value is not changed much and the MR ratio is decreased. If Er exists just below the tunnel barrier (MR ratio: black square, RA: white square), the element resistance value is increased and the MR ratio is decreased.

FIG. 34 shows a magnetoresistive element according to the comparative example.

The MTJ structure includes bottom electrode (300 nm)/Ta (5 nm)/CoFeB (3 nm)/Mg (t_{Mg} bottom nm)/MgO (0.5 nm)/CoFeB (4 nm)/Ru (0.9 nm)/CoFe (3 nm)/IrMn (10 nm)/Ta (5 nm)/top electrode (300 nm).

The magnetic layer adjacent to the bottom electrode corresponds to Ta (5 nm)/CoFeB (3 nm) and the magnetic layer adjacent to the top electrode corresponds to CoFeB (4 nm)/Ru (0.9 nm)/CoFe (3 nm)/IrMn (10 nm)/Ta (5 nm).

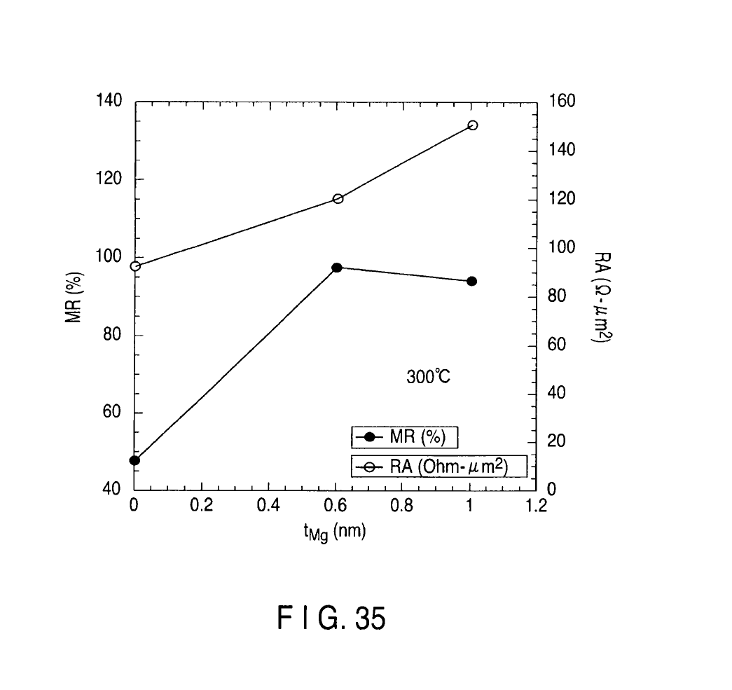

FIG. 35 shows the characteristic of the magnetoresistive element of FIG. 34.

The abscissa axis indicates a thickness t_{Mg bottom} of the low work function material Mg bottom and the ordinate axis indicates an MR ratio (left scale) and element resistance RA (right scale).

The MR ratio and element resistance RA after anneal in a magnetic field (350° C., 1 hour) were obtained for each of the case where the thickness t_{Mg bottom} of the low work function material Mg bottom was 0 nm, 0.6 nm, 1.0 nm.

As is evident from this result, when the low work function material Mg is disposed only just below the tunnel barrier, the element resistance is increased while the MR ratio is increased.

Here, a conventional object of disposing metal such as Mg just below the tunnel barrier is to prevent oxidation of the magnetic layer formed already when the tunnel barrier is formed.

That is, according to the conventional concept, the Mg just below the tunnel barrier may be oxidized completely when the tunnel barrier is formed, because oxidation of the magnetic layer can be prevented.

Thus, the thickness of Mg when Mg is formed just below the tunnel barrier is substantially 1 nm or less.

However, a prominent object of forming Mg just below the tunnel barrier in the present invention is not to prevent oxidation of the magnetic layer but to lower the resistance of the element.

Therefore, when the low work function material Mg is disposed just below the tunnel barrier, the Mg just below the tunnel barrier is formed thicker so that the non-oxide Mg is left after the tunnel barrier is formed.

As a result of verification with an experiment, it has been found that the thickness is preferred to be 1.2 nm or more while the thickness of the tunnel barrier is 0.42 to 5 nm.

By the way, the graph of FIG. 35 does not indicate data in which t_{Mg bottom} is 1.2 nm or more. In an area in which t_{Mg bottom} is 1.2 nm or more, the interface resistance RA acts in a direction of decreasing.

If Mg is formed just below the tunnel barrier, naturally, an effect of preventing the magnetic layer from being oxidized can be obtained at the same time.

### (6) Effectiveness

In the MTJ structure of the present invention, the resistance of the stack structure of the magnetic body/tunnel barrier (Schottky barrier)/semiconductor (magnetic body) is lowered, the spin mobility is improved, and the barrier dielectric strength is improved thereby enhancing the spin injection efficiency to the semiconductor.

Further, in the spin MOSFET of the present invention, the polarized spin of the ferromagnet is injected into the semiconductor through the non-magnetic body and the tunnel barrier, thereby obtaining high spin injection efficiency.

The effect of the present invention can be obtained in a magnetoresistive head also.

### 4. CONCLUSION

According to the present invention, the lowering of the resistance of the spin FET and magnetoresistive element and the improvement of the MR ratio can be achieved at the same time.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A spin FET comprising:
source/drain regions;
a channel region between the source/drain regions; and
a gate electrode above the channel region,
wherein each of the source/drain regions includes a stack structure which comprises a semiconductor substrate, a first Mg layer on the semiconductor substrate, an MgO layer as a tunnel barrier on the first Mg layer, a second Mg layer on the MgO layer, and a ferromagnet including one of CoFe and CoFeB on the second Mg layer, and,
wherein the second Mg layer has a thickness of from 0.5 nm to 5 nm.

2-6. (canceled)

7. The spin FET according to claim 1, wherein the semiconductor substrate has a first conductive type, and each of the source-drain regions includes a diffusion layer of a second conductive type which is provided in a surface region of the semiconductor substrate,
wherein the stack structures are provided on the diffusion layers.

8. The spin FET according to claim 1, wherein the stack structure is provided in a concave portion in the semiconductor substrate.

9-11. (canceled)

12. The spin FET according to claim 1, wherein the ferromagnet includes a non-magnetic material.

13. (canceled)

14. The spin FET according to claim 1, wherein the surface region of the semiconductor substrate is comprised of one of Si, Ge, GaAs and ZnSe.

15. The spin FET according to claim 1, wherein a magnetization direction of the ferromagnet of one of the source/drain regions is pinned by an antiferromagnet.

16. The spin FET according to claim 15, wherein the antiferromagnet is comprised of one of IrMn, PtMn and NiMn.

17. A reconfigurable logic circuit comprising:
the spin FET according to claim 1, wherein a logic is determined by data which is stored as a relationship of the magnetization directions of the ferromagnets of the source/drain regions.

18-20. (canceled)
